(19) United States
(12) Patent Application Publication
(10) Pub. No.: US 2016/0133589 A1
(43) Pub. Date: May 12, 2016

(54) SILICON SPACE TRANSFORMER FOR IC PACKAGING

(71) Applicant: Intel Corporation, Santa Clara, CA (US)

(72) Inventors: Debendra Mallik, Chandler, AZ (US); Robert L. Sankman, Phoenix, AZ (US); Sujit Sharan, Chandler, AZ (US)

(21) Appl. No.: 14/996,795

(22) Filed: Jan. 15, 2016

Related U.S. Application Data
(63) Continuation of application No. 13/929,001, filed on Jun. 27, 2013, now abandoned.

(51) Int. Cl. H01L 23/00; H01L 23/498

(52) U.S. Cl. CPC H01L 24/09; H01L 23/49827; H01L 2224/0903; H01L 2224/09181

(57) ABSTRACT

An apparatus includes at least a first integrated circuit (IC) and a wafer-fabricated space transformer (ST). The IC includes bonding pads of a first inter-pad pitch on a bottom surface. The ST includes a top surface having bonding pads of the first inter-pad pitch, and at least a portion of the bonding pads of the first IC are bonded to the bonding pads of the top surface. The ST includes a bottom surface having bonding pads of a second inter-pad pitch, at least one dielectric insulating layer between the top surface and the bottom surface, and conductive interconnect in the dielectric layer configured to provide electrical continuity between the bonding pads of the top surface and the bonding pads of the bottom surface.

### PRIORITY APPLICATION

This application is a continuation of U.S. application Ser. No. 13/929,001, filed Jun. 27, 2013, which is incorporated herein by reference in its entirety.

### TECHNICAL FIELD

Embodiments pertain to packaging of integrated circuits. Some embodiments relate to integrated circuit sockets.

### BACKGROUND

Electronic systems often include integrated circuits (ICs) that are connected to a subassembly such as a substrate or motherboard. The ICs can be packaged and inserted into an IC package that is mounted on the subassembly. As electronic system designs become more complex, it is a challenge to meet the desired size constraints of the system. One aspect that influences the overall size of a design is the spacing required for the interconnection of the contacts of the IC packages. As the spacing is reduced, the packaged ICs can become less robust and the cost of meeting the spacing requirements can increase. Thus, there are general needs for devices, systems and methods that address the spacing challenges for contacts of ICs yet provide a robust and cost effective design.

### BRIEF DESCRIPTION OF THE DRAWINGS

FIG. 1 shows an illustration of an example of a device that includes an assembly or package for at least one IC in accordance with some embodiments;

FIG. 2 shows an illustration of an example of a device that includes a first IC and a second IC arranged on a space transformer in accordance with some embodiments;

FIG. 3 shows an illustration of another example of a device that includes an IC arranged on a space transformer in accordance with some embodiments;

FIG. 4 shows an illustration of still another example of a device that includes an IC on a space transformer in accordance with some embodiments;

FIG. 5 shows an illustration of still another example of a device that includes an IC on a space transformer in accordance with some embodiments; and

FIG. 6 shows a flow diagram of an example of a method of forming an assembly that includes at least one IC in accordance with some embodiments;

FIG. 7 shows an illustration of multiple views of a multi-chip space transformer in accordance with some embodiments;

FIG. 8 illustrates additional stages of the assembly of a multi-chip space transformer in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The demand for increased computing power in smaller devices has led to increased use of system on chip (SoC) packaging. The requirement of increased computer performance with smaller size can lead to a high number of signals to be provided to and received by the IC package. The large number of signals may require a finer pitch for the input-output (I/O) interconnection between a SoC and other electronic components such as memory, display, a communications bus, etc. However, finer pitch for I/O can lead to expensive packaging to accommodate the finer geometries associated with the width of interconnection lines, spacing between interconnection, and spacing to protect against electro-migration between interconnect. This leads to packaging requirements that conflict with the need for lower cost. One approach is to add a component to the IC package that fans out the I/O to a larger pitch. Some of the problems with such a component is that the component is required to have a significant thickness (e.g., 100 micrometers (μm) or microns) to allow handling during assembly, the component increases the cost of the SoC, and may add higher capacitance and resistance to the I/O.

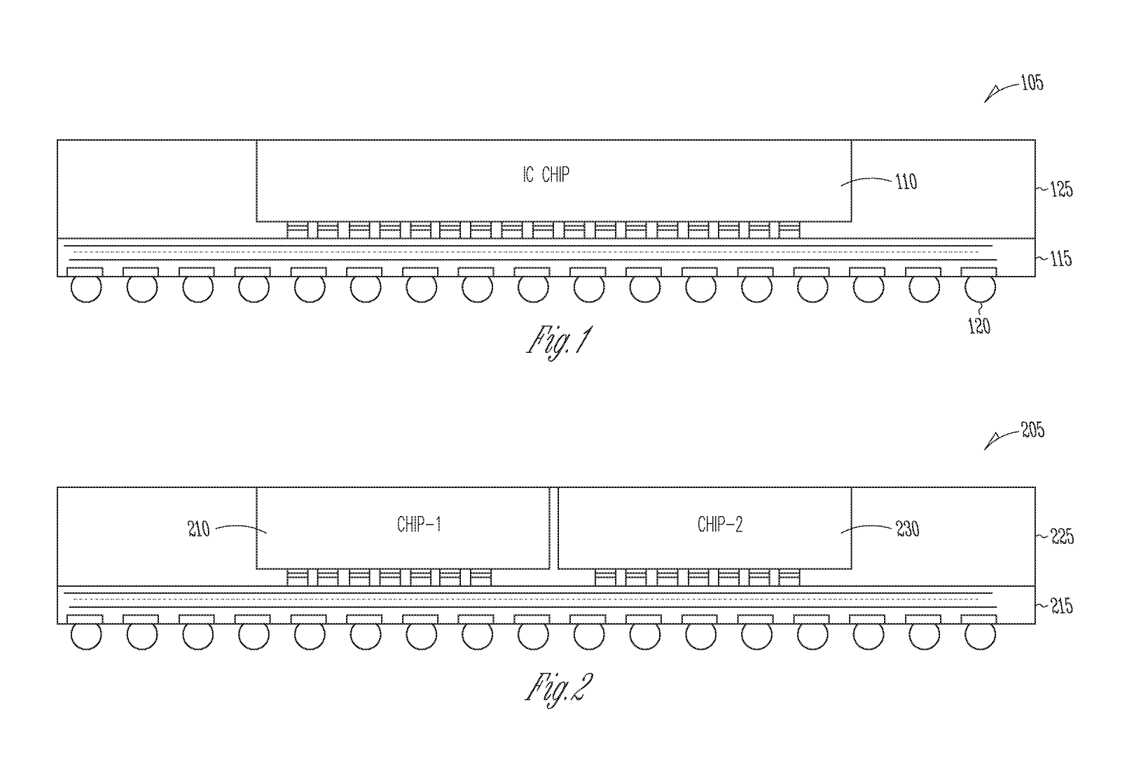

FIG. 1 shows an illustration of an example of a device 105 that includes an assembly or package for at least one IC. The device 105 includes at least a first IC 110 that has bonding pads on a bottom surface of the IC 110. The bonding pads can provide electrical continuity to electronic devices fabricated in the IC. The bonding pads have a first inter-pad pitch. The first inter-pad pitch is a fine pitch to accommodate the density of the I/O of the IC 110. The device 105 also includes a wafer-fabricated space transformer (ST). The ST 115 includes a top surface having bonding pads, and the bonding pads on the top surface have the first inter-pad pitch. At least a portion of the bonding pads of the IC 110 are bonded to the bonding pads of the top surface of the ST 115. The Figure also shows a polymer layer 125 (e.g., a mold compound) with the IC 110 arranged within the polymer layer 125 and to cover the bonds on the top surface. In some examples, the device 105 includes an underfill layer on the top surface of the ST 115 and the polymer layer is arranged above the underfill layer.

The ST 115 also includes a bottom surface having bonding pads, and the bonding pads of the bottom surface have a second inter-pad pitch. The Figure shows solder bumps 120 attached to the bonding pads. The second inter-pad pitch is larger or is more coarse than the first inter-pad pitch and has lower pad density. The lower pad density means the second inter-pad pitch may have a lower number of solder bumps per square millimeter (bumps/mm²) than the first inter-pad pitch. The ST 115 also includes at least one dielectric insulating layer between the top surface and the bottom surface. The dielectric layer can include conductive interconnects to provide electrical continuity between the bonding pads of the top surface of the ST 115 and the bonding pads of the bottom surface of the ST 115. Thus, the ST 115 provides a translation between the density of the first inter-pad pitch and the density of the second inter-pad pitch.

In some examples, the ST 115 includes a plurality of dielectric insulating layers between the top surface and the bottom surface. The conductive interconnect can include at least one metal layer between the top surface and the bottom surface. The metal layer can be patterned (e.g., with one or both of conductive traces and vias) to provide the electrical continuity between the bonding pads of the top surface and the bonding pads of the bottom surface of the ST 115. The dielectric layers and the at least one metal layer can be formed using a wafer fabrication process. Because the ST 115 is formed using a wafer fabrication process, the top surface of the ST 115 can accommodate line width and spacing of one micron (1 μm) or less. Additionally, because the ST 115 is fabricated using the wafer fabrication process, the ST is substantially flat and expansion matched to the IC 110. This allows the assembly connections between the IC 110 and the ST 115 to have the fine first inter-pad pitch (e.g., 10 μm or less).

The ST 115 can be formed on a substrate of bulk silicon (e.g., starting with a silicon wafer) and removed from the substrate using at least one of back-grinding, cleaving, fly-cutting, chemical mechanical polishing (CMP), dry etching, or wet etching. This can result in an ST 115 having dielectric insulating layers that include silicon dioxide (SiO₂) and exclude bulk silicon. The resulting ST 115 can also be thin (e.g., approximately 10-20 μm). Thus, the thickness of the ST 115 does not significantly impact the overall size of the device 105.

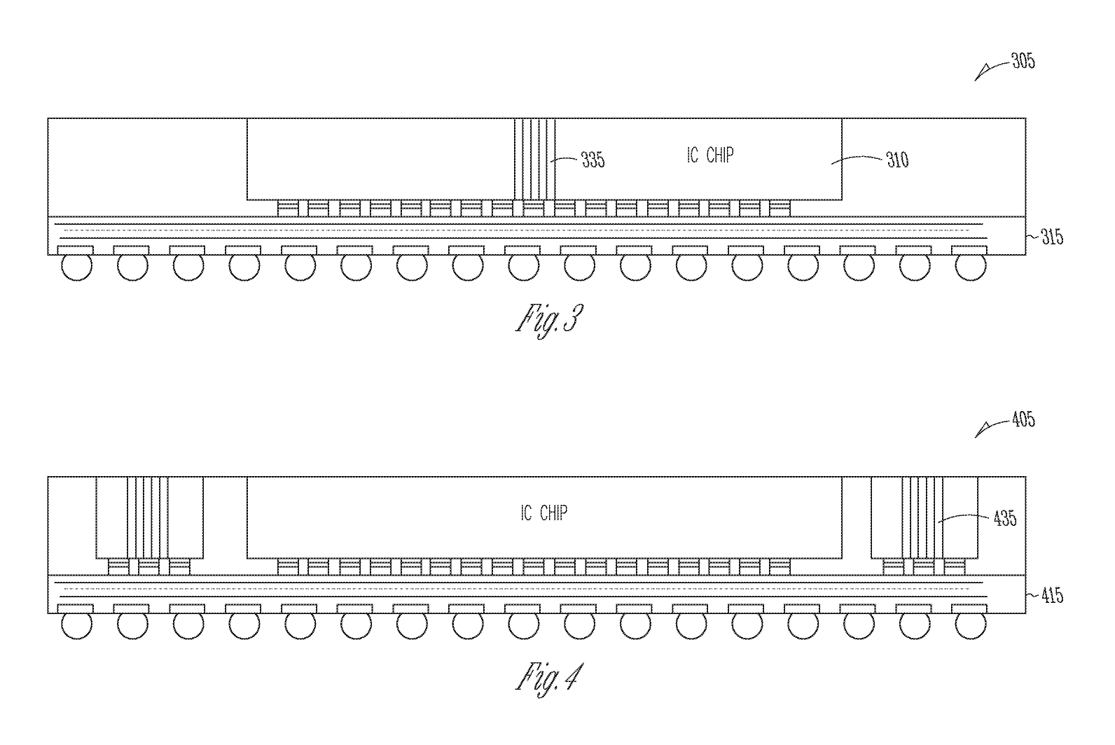

FIG. 2 shows an illustration of an example of a device 205 that includes a first IC 210 arranged on an ST 215 and a second IC 230 arranged on the ST 215. One or both of the first IC 210 and the second IC 230 can be a packaged IC. The second IC 230 includes bonding pads and at least a portion of the bonding pads are bonded to the bonding pads on the top surface of the ST 215. The ST 215 includes conductive interconnect to provide electrical continuity between at least the same portion or a different portion of the bonding pads of the first IC and at least the same or a different portion of the bonding pads of the second IC.

Because the ST 215 is formed using wafer fabrication processes, the density of the interconnection on the top surface of the ST 215 can approach the interconnect density used on upper layers of conventional on-chip interconnection. This allows the ST 215 to be used in assembly of a complex die using mixed process ICs. For example, the first IC 210 may include a processor core formed using a 10 nanometer (nm) process and the second IC may include a memory IC formed using a 17 nm process. The complex die can be expanded beyond the two-IC example. The ST 215 may include several types of ICs as a SoC. The ICs can include any combination of ICs formed using a logic silicon process, a photonics process, a micro-electromechanical (MEMS) process, a memory process, etc.

Other arrangements can be useful. For instance, the second IC 230 can be arranged on top of the first IC 210 with the first IC 210 bonded to the ST 215. The top surface of the first IC 210 can include bonding pads and the bottom surface of the second IC 230 can include bonding pads. At least a portion of the bonding pads of the bottom surface of the second IC 230 can be bonded to the bonding pads of the top surface of the first IC 210. A polymer layer 225 may enclose both the first and second ICs, and the ICs may be formed using different IC fabrication processes.

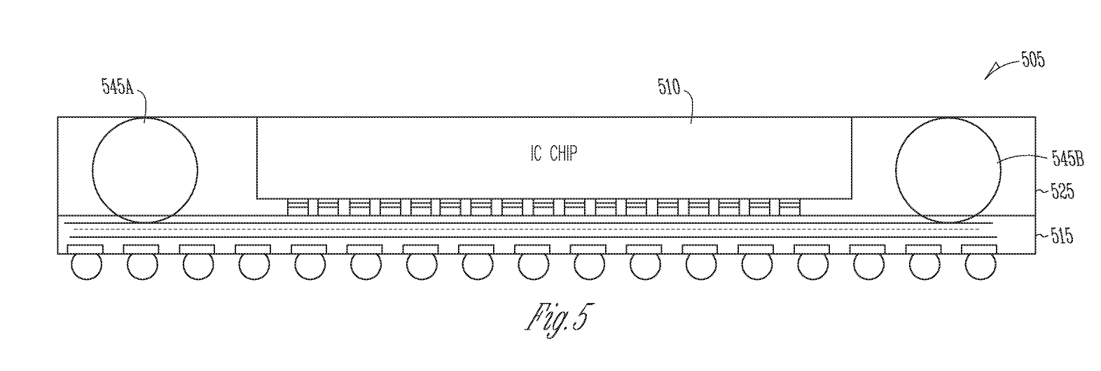

FIG. 3 shows an illustration of another example of a device 305 that includes an IC 310 on an ST 315. The IC 310 includes at least one through-silicon-via (TSV) 335. In some examples, the device 305 includes a second IC (not shown) arranged on the ST 315 (e.g., next to the first IC 310). The ST 315 can include conductive interconnect to provide electrical continuity from the TSV 335 to a bonding pad of the second IC. In some examples, the second IC can be arranged on top of the IC 310 in FIG. 3. The TSV 335 may provide electrical continuity from a bonding pad on the bottom surface of the ST 315 to a bonding pad on the bottom surface of the second IC. In some examples, the device 305 includes the first IC 310, the second IC on top of the first IC 310, and a third IC (not shown) arranged on the ST 315 (e.g., next to the first IC 310) and having bonding pads. The first IC 310 can include at least one TSV 335 that may provide electrical continuity from a bonding pad on the bottom surface of the second IC to the top surface of the ST 315 and to a bonding pad of the third IC.

FIG. 4 shows an illustration of another example of a device 405 that includes an IC 410 on an ST 415. In the example shown, the device 405 includes at least one passive electrical device on the ST 415. Two passive electrical devices 440A and 440B are shown in the Figure. The passive electrical device may include only passive circuit components (e.g., resistors, capacitors, etc.) rather than active circuit components (e.g., transistors). The passive device also includes at least one TSV 435, and bonding pads having the first inter-pad pitch. At least a portion of the bonding pads of the bottom surface of the passive electrical device are bonded to the bonding pads of the top surface of the ST 415. The device 405 can also include a second IC (not shown) arranged on top of the passive electrical device. The bottom surface of the second IC includes bonding pads and the second IC is bonded to the TSV of the passive electrical device. The TSV 435 provides electrical continuity from a bonding pad on the top surface of the ST to a bonding pad on the bottom surface of the second IC.

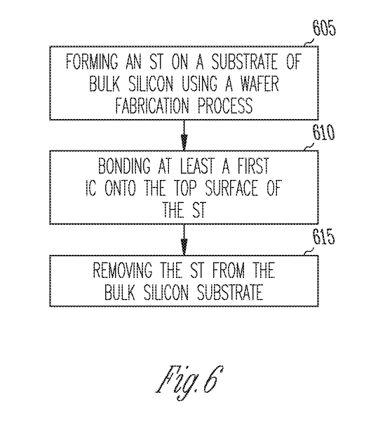

FIG. 5 shows an illustration of another example of a device 505 that includes an IC 510 arranged on an ST 515. The device 505 includes a molded polymer layer 525 on the top surface of the ST 515, and the IC 510 is arranged within the polymer layer. The device 505 can include a second IC (not shown) having bonding pads and arranged above the IC 510 shown. The device includes at least one through-mold interconnect (TMI) arranged in the molded polymer layer 525. A TMI can be made by forming one or more vias in the molded polymer layer 525 and filling the one or more vias with solder. Two TMI structures 545A and 545B are shown. The TMI provides electrical continuity through the molded polymer layer 525. In the example shown in the Figure, the TMI provides electrical continuity from a bonding pad on the bottom surface of the ST to a bonding pad on the bottom surface of the second IC.

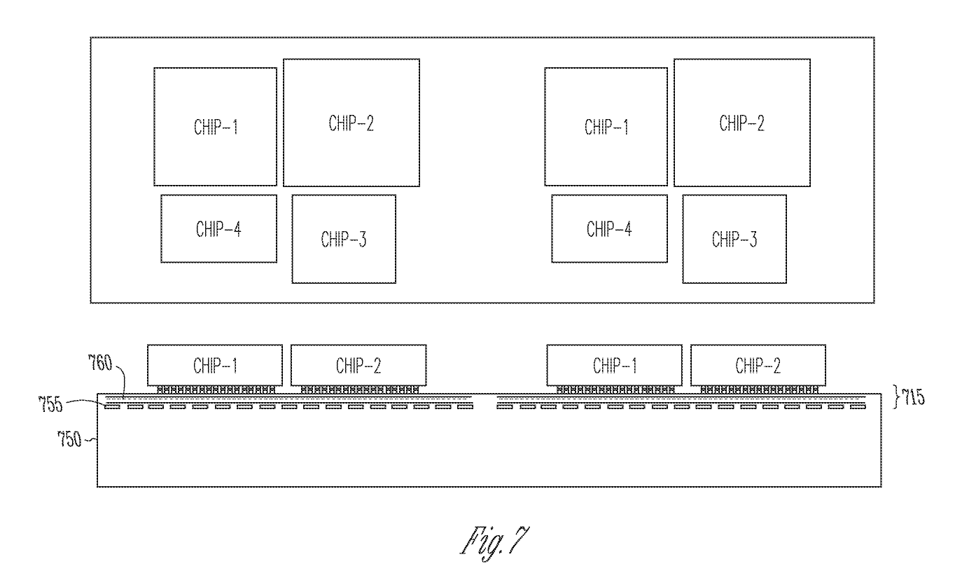

FIG. 6 shows a flow diagram of an example of a method 600 of forming an assembly that includes at least one IC. At block 605, an ST is formed on a substrate of bulk silicon (e.g., a silicon wafer) using a wafer fabrication process. The ST includes at least one dielectric layer between a top surface of the ST and a bottom surface of the ST. The dielectric layer includes conductive interconnect and the top surface of the ST includes bonding pads having a first inter-pad pitch.

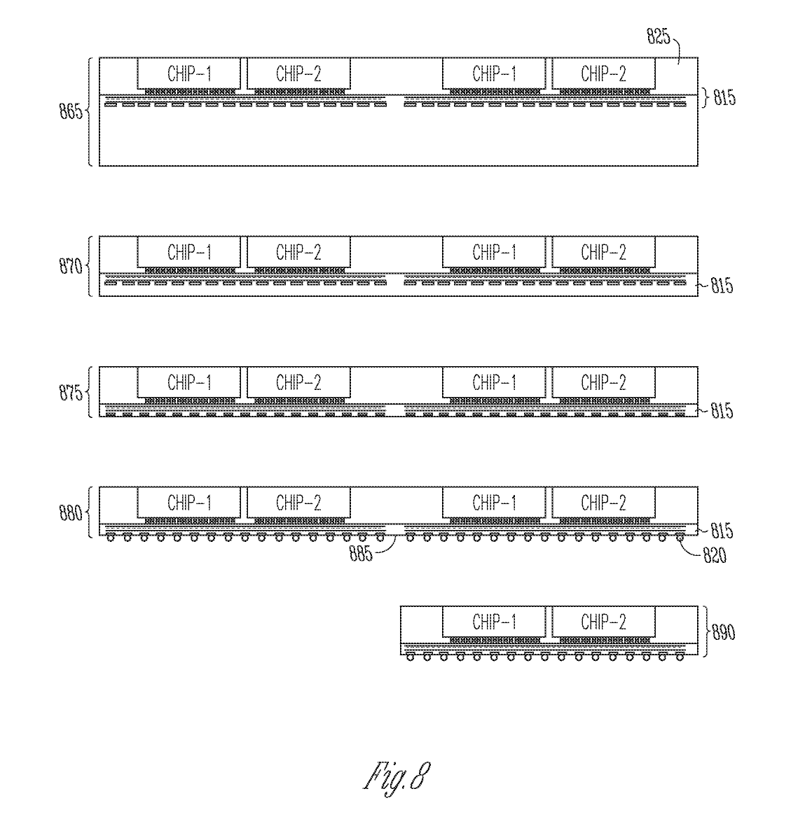

At block 610, at least a first integrated circuit (IC) is bonded onto the top surface of the ST. The IC includes bonding pads on a bottom surface of the IC, and the bonding pads have the first inter-pad pitch. FIG. 7 shows a top view and a side view of a multi-chip ST. The Figure shows a portion of a wafer that includes two four-IC modules, such as two four-chip SoC's for example. The SoC's may be later separated into individual multi-chip STs. The four ICs can be formed using different processes. For example, the four ICs may include a processor core, a graphics processor core, an I/O chip and a memory chip. The ST wafer may contain many such multi-chip modules. In the example shown, the ST 715 is formed near the top of the substrate 750. The ST 715 includes bonding pads with an inter-pad pitch to match a fine pitch of the ICs or chips. The example shows the ST having bonding pads 755 at this stage that have a second inter-pad pitch, but these pads may alternatively be formed in later steps. One or more metal layers 760 provide electrical continuity between the bonding pads of the top surface and the bonding pads of the bottom surface.

FIG. 8 illustrates additional stages of the assembly of FIG. 7. The top assembly 865 shows a polymer layer 825 is formed on the top surface of the ST wafer. The polymer layer 825 may be a molded polymer layer that includes the ICs arranged within the polymer layer.

Returning to FIG. 6 at block 615, the ST is removed from the substrate of bulk silicon. This is shown in the second assembly 875 of FIG. 8. As explained previously herein, the ST 815 can be removed from the bulk silicon substrate using at least one of back-grinding, cleaving, fly-cutting, chemical mechanical polishing (CMP), dry etching, or wet etching.

The bottom surface of the ST 815 in assembly 875 includes bonding pads having a second inter-pad pitch different (e.g., a larger pitch) from the first inter-pad pitch. In some examples, the bonding pads can be deposited onto the bottom surface of the ST 815 after the ST 815 is removed from the bulk silicon instead of being formed as a layer in the early stages. Solder bumps can be added at the wafer level if desired as shown in assembly 880.

The conductive interconnect of the at least one dielectric layer of the ST 815 may provide electrical continuity between the bonding pads of the top surface of the ST and the bonding pads of the bottom surface of the ST. In some examples, the conductive interconnect of the at least one dielectric layer may provide electrical continuity between bonding pads of separate ICs (e.g., between bonding pads of chip 1 and chip 2 in FIG. 8).

The resulting ST 815 can be quite thin (e.g., 10-20 μm) with the molded polymer layer 825 adding strength during wafer handling. The ST wafer can include saw streets 885 to facilitate singulating (e.g., dicing) the wafer into individual product die 890. The individual die 890 can be used on a package substrate or can be mounted directly to a printed circuit board (PCB) of an electronic system, such as a system motherboard for example. The PCB can include bonding pads having the larger inter-pad pitch. At least a portion of the bonding pads of the bottom surface of the ST 815 can be in electrical communication with the bonding pads of the PCB.

The devices, systems, and methods described that use an ST can allow for significantly higher density of interconnection between ICs within a multichip ST die in comparison to conventional multichip packaging approaches. Use of an ST can provide cost effective approach for forming complex die using mixed-process ICs.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

### Additional Examples

Example 1 can include subject matter (such as an apparatus) including at least a first IC and a wafer-fabricated space transformer. The IC includes bonding pads on a bottom surface of the IC, and the bonding pads have a first inter-pad pitch. The space transformer (ST) includes a top surface and a bottom surface. The top surface includes bonding pads that have the first inter-pad pitch and at least a portion of the bonding pads of the first IC are bonded to the bonding pads of the top surface. The bottom surface includes bonding pads having a second inter-pad pitch. The ST can also include at least one dielectric insulating layer between the top surface and the bottom surface, and conductive interconnect in the dielectric layer configured to provide electrical continuity between the bonding pads of the top surface and the bonding pads of the bottom surface.

In Example 2, the subject matter of Example 1 can optionally include a plurality of dielectric insulating layers between the top surface and the bottom surface of the ST. The conductive interconnect includes at least one metal layer between the top surface and the bottom surface, and the at least one metal layer is patterned to provide the electrical continuity between the bonding pads of the top surface and the bonding pads of the bottom surface of the ST.

In Example 3, the subject matter of Example 2 optionally includes a plurality of dielectric layers and at least one metal layer that are formed using a wafer fabrication process. The dielectric insulating layers can include silicon dioxide (SiO₂) and exclude bulk silicon.

In Example 4, the subject matter of one or any combination of Examples 1-3 optionally includes a second IC arranged on the ST. The second IC includes bonding pads, and at least a portion of the bonding pads of the second IC are bonded to the bonding pads of the top surface of the ST. The ST includes conductive interconnect to provide electrical continuity between at least the same portion or a different portion of the bonding pads of the first IC and at least the same or a different portion of the bonding pads of the second IC.

In Example 5, the subject matter of Example 4 optionally includes at least one through-silicon-via (TSV). The ST optionally includes conductive interconnect to provide electrical continuity from the TSV to a bonding pad of the second IC.

In Example 6, the subject matter of one or any combination of Examples 1-5 optionally includes a polymer layer on the top surface of the ST, wherein the first IC is arranged within the polymer layer.

In Example 7, the subject matter of one or any combination of Examples 1-6 optionally includes an underfill layer on the top surface of the ST and a polymer layer arranged above the underfill layer. The first IC is arranged within the polymer layer.

In Example 8, the subject matter of one or any combination of Examples 1-7 optionally includes a second IC arranged on top of the first IC. A top surface of the first IC includes bonding pads and a bottom surface of the second IC includes bonding pads, wherein at least a portion of the bonding pads of the bottom surface of the second IC are bonded to the bonding pads of the top surface of the first IC.

In Example 9, the subject matter of one or any combination of Examples 4-8 optionally includes a first IC formed using an IC fabrication process different from an IC fabrication process used to form a second IC.

In Example 10, the subject matter of one or any combination of Examples 4-9 optionally includes a first IC that includes at least one TSV, and wherein the at least one TSV provides electrical continuity from a bonding pad on the bottom surface of the ST to a bonding pad on the bottom surface of the second IC.

In Example 11, the subject matter of one or any combination of Examples 8-10 optionally includes a third IC arranged on the ST and including bonding pads, wherein the first IC includes at least one TSV, and wherein the at least one TSV provides electrical continuity from a bonding pad on the bottom surface of the second IC to the top surface of the ST and to a bonding pad of the third IC.

In Example 12, the subject matter of one or any combination of Examples 1-11 optionally includes a passive electrical device including only passive circuit components, at least one TSV, and bonding pads having the first inter-pad pitch. At least a portion of the bonding pads of the bottom surface of the passive electrical device are bonded to the bonding pads of the top surface of the ST. The examples also optionally include a second IC arranged on top of the passive electrical device, wherein a bottom surface of the second IC includes bonding pads. The at least one TSV of the passive electrical device optionally provides electrical continuity from a bonding pad on the top surface of the ST to a bonding pad on the bottom surface of the second IC.

In Example 13, the subject matter of one or any combination of Examples 1-12 optionally includes a molded polymer layer on the top surface of the space transformer, wherein the first IC is arranged within the polymer layer, a second IC arranged above the first IC, wherein a bottom surface of the second IC includes bonding pads, and at least one through-mold interconnect (TMI) arranged in the polymer layer, wherein the TMI provides electrical continuity from a bonding pad on the bottom surface of the ST to a bonding pad on the bottom surface of the second IC.

In Example 14, the subject matter of one or any combination of Examples 1-13 optionally includes the second inter-pad pitch being larger than the first inter-pad pitch.

Example 15 can include subject matter, or can optionally be combined with one or a combination of Examples 1-14 to include subject matter (such as a method, means for performing acts, or a machine readable medium that can cause the machine to perform acts), including forming an ST on a substrate of bulk silicon using a wafer fabrication process, wherein the ST includes at least one dielectric layer between a top surface and a bottom surface of the ST, wherein the at least one dielectric layer includes conductive interconnect and the top surface of the ST includes bonding pads having a first inter-pad pitch, bonding at least a first integrated circuit (IC) onto the top surface of the ST, wherein the IC includes bonding pads on a bottom surface of the IC, wherein the bonding pads have the first inter-pad pitch, and removing the ST from the bulk silicon substrate, wherein the bottom surface of the ST includes bonding pads having a second inter-pad pitch different from the first inter-pad pitch, and wherein the conductive interconnect provides electrical continuity between the bonding pads of the top surface of the ST and the bonding pads of the bottom surface of the ST.

In Example 16, the subject matter of Example 15 can optionally include forming a plurality of dielectric insulating layers and at least one metal layer using the wafer fabrication process, wherein the at least one metal layer is patterned to provide the electrical continuity between the bonding pads of the top surface and the bonding pads of the bottom surface.

In Example 17, the subject matter of one or any combination of Examples 15 and 16 optionally includes removing the ST from the bulk silicon using at least one of back-grinding, cleaving, fly-cutting, chemical mechanical polishing (CMP), dry etching, or wet etching.

In Example 18, the subject matter of one or any combination of Examples 15-17 optionally includes adding the bonding pads to the bottom surface of the ST after the ST is removed from the bulk silicon.

In Example 19, the subject matter of one or any combination of Examples 15-18 optionally includes forming a polymer layer on the top surface of the ST that includes the first IC arranged within the polymer layer.

In Example 20, the subject matter of one or any combination of Examples 15-19 optionally includes forming a polymer layer on the top surface of the ST that includes the first IC arranged within the polymer layer.

In Example 21, the subject matter of one or any combination of Examples 15-19 optionally includes forming a polymer layer on the top surface of the ST with at least one TMI arranged in the polymer layer, arranging a second IC above the first IC, wherein the second IC is a packaged IC and wherein a bottom surface of the second IC includes bonding pads, and bonding the at least one TMI to a bonding pad on the bottom surface of the second IC and a bonding pad on the top surface of the ST to provide electrical continuity from a bonding pad on the bottom surface of the ST to the bonding pad on the bottom surface of the second IC.

In Example 22, the subject matter of one or any combination of Examples 15-21 optionally includes arranging a second IC on the ST, and bonding at least a portion of bonding pads of a bottom surface of the second IC to bonding pads of the top surface of the ST, wherein the second IC is formed using an IC fabrication process different from an IC fabrication process used to form the first IC.

In Example 23, the subject matter of one or any combination of Examples 15-22 optionally includes arranging a second IC on top of the first IC, and bonding at least a portion of bonding pads of a bottom surface of the second IC to bonding pads of a top surface of the first IC, wherein the second IC is formed using an IC fabrication process different from an IC fabrication process used to form the first IC.

In Example 24, the subject matter of one or any combination of Examples 15-23 optionally includes arranging a passive electrical device on the top surface of the ST, wherein the passive electrical device includes only passive circuit components and at least one TSV, and bonding the at least one TSV of the passive electrical device to at least one bonding pad of the bottom surface of the second IC and to at least one bonding pad of the top surface of the ST to provide electrical continuity from the bonding pad on the bottom surface of the second IC to a bonding pad on the bottom surface of the ST.

In Example 25, the subject matter of one or any combination of Examples 15-24 optionally includes arranging a second IC on the top surface of the ST, bonding at least one TSV of the first IC to a bonding pad on the top surface of the ST to provide electrical continuity between the first IC and the second IC.

Example 26 can include subject matter, or can optionally be combined with one or a combination of Examples 1-14 to include subject matter (such as a system), including at least a first IC having bonding pads on a bottom surface, wherein the bonding pads have a first inter-pad pitch, a wafer-fabricated ST, and a printed circuit board (PCB). The ST can include a top surface having bond pads, wherein the bonding pads have the first inter-pad pitch and wherein at least a portion of the bonding pads of the first IC are bonded to the bonding pads of the top surface, a bottom surface having bonding pads, wherein the bonding pads have a second inter-pad pitch, at least one dielectric layer between the top surface and the bottom surface, and conductive interconnect in the dielectric layer configured to provide electrical continuity between the bonding pads of the top surface and the bonding pads of the bottom surface. The PCB includes bonding pads and at least a portion of the bonding pads of the bottom surface of the ST are in electrical communication with the bonding pads of the PCB.

In Example 27, the subject matter of Example 26 optionally includes the bonding pads of the PCB having the second inter-pad pitch, and at least a portion of the bonding pads of the bottom surface of the ST are bonded to the bonding pads of the PCB.

In Example 28, the subject matter of one or any combination of Examples 26 and 27 optionally includes a second IC arranged on a top surface of the ST, and a package substrate having a first surface and a second surface, wherein the first surface includes bonding pads having the second inter-pad pitch. The ST can be ST arranged on the first surface of the package substrate, and the second surface of the package substrate includes bonding pads bonded to the PCB.

In Example 29, the subject matter of one or any combination of Examples 26-28 optionally includes a first IC that includes a processor core and a second IC that is a memory IC.

Example 30 can include subject matter, or can optionally be combined with any portion or combination of any portions of any one or more of Examples 1 through 29 to include subject matter, that can include means for performing any one or more of the functions of Examples 1 through 29, or a machine-readable medium including instructions that, when performed by a machine, cause the machine to perform any one or more of the functions of Examples 1 through 29.

Each of these non-limiting examples can stand on its own, or can be combined in various permutations or combinations with one or more of the other examples.

What is claimed is:

1. An apparatus comprising:
at least a first integrated circuit (IC) having bonding pads on a bottom surface, wherein the bonding pads have a first inter-pad pitch; and
a wafer-fabricated space transformer (ST), including:
a top surface having bonding pads, wherein the bonding pads have the first inter-pad pitch and wherein at least a portion of the bonding pads of the first IC are bonded to the bonding pads of the top surface;
a bottom surface having bonding pads, wherein the bonding pads have a second inter-pad pitch;
at least one dielectric insulating layer between the top surface and the bottom surface; and
conductive interconnect in the dielectric layer configured to provide electrical continuity between the bonding pads of the top surface and the bonding pads of the bottom surface.
